(19) United States
(12) Patent Application Publication
(10) Pub. No.: US 2007/0295496 A1
(43) Pub. Date: Dec. 27, 2007

(54) Diamond Composite Heat Spreader

(76) Inventors: David R. Hall, Provo, UT (US); Joe Fox, Spanish Fork, UT (US); Ronald Crockett, Payson, UT (US); Tyson J. Wilde, Spanish Fork, UT (US)

Correspondence Address: TYSON J. WILDE;NOVATEK INTERNATIONAL, INC., 2185 SOUTH LARSEN PARKWAY, PROVO, UT, 84606, US

(21) Appl. No.: 11/426,255

(22) Filed: Jun. 23, 2006

(51) Int. Cl. H05K 7/20

(52) U.S. Cl. 165/185; 361/704; 257/720

(57) ABSTRACT

A composite heat spreader is disclosed in one embodiment of the invention as including an input interface to conduct heat from a heat source, such as an integrated circuit, and an output interface to transfer heat to a heat sink. A support material having a first thickness is provided between the input interface and the output interface. One or more diamond monocrystals are embedded in the support material and have a second thickness which is at least 20% of the first thickness. In some embodiments, the diamond monocrystals extend from the input interface to the output interface. These one or more diamond monocrystals may be either rough or finished diamonds.

### BACKGROUND OF THE INVENTION

1. Field of the Invention

The present invention relates to heat spreaders and more particularly to diamond or diamond composite heat spreaders.

2. Background

Integrated circuit line-width reductions to 90 nm and below continue to provide higher performance and functional integration by allowing greater numbers of components to be packed onto a single chip. These continued size reductions, however, bring with them various problems or potential problems, such as increased current and power densities, increased leakage current, packaging problems, and lower heat conductivity associated with low-k dielectrics. Furthermore, one significant but often overlooked challenge associated with these size reductions is the availability of heat sinks to dissipate the heat produced by these densely packed devices.

Another emerging problem of these size reductions are temperature variations, or “hot spots,” on a chip. In some cases, temperatures can vary by as much as 50° C. across a chip. Even greater temperature variations may exist in a chip's metal layers. The practical result is that chip designers must now be concerned about heat and temperature gradients in addition to other design concerns. In some cases, the location of “hot spots” may actually drive chip design methodologies and power management schemes. This constitutes a significant break from conventional design methodologies, which often assume a constant temperature for all components and interconnects of a chip when analyzing the chip's electrical characteristics.

To transport heat away from an integrated circuit, diamond or diamond composite heat spreaders have shown significant promise because of their exceptionally high thermal conductivity and diffusivity. For example, the thermal conductivity of diamond is many times higher than either copper or aluminum, the most common materials used in current heat sinks. Furthermore, because of its very low heat capacity, diamond exhibits far greater thermal diffusivity than either copper or aluminum. These properties make diamond an ideal candidate for use in heats spreader to quickly disperse or dissipate heat from a heat source without storing it.

Nevertheless, diamond heat spreaders have still been unable to gain wide use or acceptance. Key reasons for this include the expense of diamond, the inability to cheaply find or grow diamond crystals of sufficient size and thickness for use in heat spreaders, the inert nature of diamond making it difficult to bond to other materials, and the like. To overcome some of these problems, some sources have disclosed heat spreaders which include smaller and less expensive diamond particles embedded in other materials, such as copper. Nevertheless, these heat spreaders reduce the effectiveness of diamond by embedding the diamond in less thermally conductive materials. These materials reduce the overall thermal conductivity of the heat spreader by creating undesirable thermal barriers between each of the diamond particles.

In view of the foregoing, what are needed are heat spreaders better able to capitalize on the desirable thermal properties of diamond. More particularly, heat spreaders are needed that will provide a continuous or substantially continuous thermal pathway between a heat source and a heat sink, while eliminating or reducing thermal barriers typical of prior diamond composite heat spreaders. Ideally, such a heat spreader would strategically utilize diamond crystals to minimize the cost of the heat spreader, while maximizing its effectiveness. Such a heater spreader could also be used to deliberately diffuse heat generated at “hot spots” or other selected areas of an integrated circuit.

### SUMMARY OF THE INVENTION

Consistent with the foregoing, and in accordance with the invention as embodied and broadly described herein, a composite heat spreader is disclosed in one embodiment of the invention as including an input interface to conduct heat from a heat source, such as an integrated circuit, and an output interface to transfer heat to a heat sink. A support material comprising a first thickness is provided between the input interface and the output interface. One or more diamond monocrystals are embedded in the support material and comprise a second thickness which is at least 20% of the first thickness. In some embodiments, the second thickness is at least 25%, 35%, 50% or 70% of the first thickness. In some embodiments the diamond monocrystals extends from the input interface to the output interface. These one or more diamond monocrystals may be either rough or finished diamonds.

In certain embodiments, the one or more of the diamond monocrystals are strategically positioned within the support material to align with hot spots, vias, conductors, or other locations of a heat source. This may provide efficient use of the diamond monocrystals by positioning them where they are needed most.

In certain embodiments, the support material may contain diamond grains. In selected embodiments, these diamond grains may also be compacted and sintered together to form polycrystalline compact diamond. Similarly, during formation of the polycrystalline compact diamond, these diamond grains may be intergrown with each other, the diamond monocrystal, or both, to improve the thermal conductivity of the support material In other embodiments, the support material may include other materials such silicon, metals, cubic boron nitride, ceramics, carbides, polycrystalline silicon, to name just a few.

In another embodiment in accordance with the invention, a method for spreading heat generated by a heat source may include conducting, at an input interface, heat from a heat source and transferring heat to a heat sink through an output interface. The method further includes providing a support material between the input interface and the output interface, and embedding one or more diamond monocrystals in the support material. Some or all of these diamond monocrystals extend from the input interface to the output interface.

In yet another embodiment of the invention, a heat spreading assembly in accordance with the invention may include an integrated circuit, a heat sink, and a composite heat spreader inserted between the integrated circuit and the heat sink. The composite heat spreader includes an input interface to conduct heat from the integrated circuit and an output interface to transfer heat to the heat sink. A support material is provided between the input interface and the output interface and one or more diamond monocrystals are embedded in the support material. These diamond monocrystals extend from the input interface to the output interface.

Disclosed herein is a novel heat spreader and associated method for transporting heat between a heat source and a heat sink. The features and advantages of apparatus and methods in accordance with the invention will become more fully apparent from the following description and appended claims, or may be learned by the practice of the invention as set forth hereinafter.

### BRIEF DESCRIPTION OF THE DRAWINGS

In order to describe the manner in which the above-recited features and advantages of the present invention are obtained, a more particular description of apparatus and methods in accordance with the invention will be rendered by reference to specific embodiments thereof, which are illustrated in the appended drawings. Understanding that these drawings depict only typical embodiments of the present invention and are not, therefore, to be considered as limiting the scope of the invention, apparatus and methods in accordance with the present invention will be described and explained with additional specificity and detail through the use of the accompanying drawings in which:

FIG. 1 is a cross-sectional profile view showing one embodiment of a heat spreader in accordance with the invention;

FIG. 2 is a cross-sectional profile view showing another embodiment of a heat spreader in accordance with the invention;

FIG. 3 is a cross-sectional profile view of one embodiment of a heat spreader using unfinished diamonds;

FIG. 4 is a cross-sectional profile view of one embodiment of a heat spreader showing intergrowth between diamond crystals in the support material;

FIG. 5 is a cross-sectional profile view of another embodiment of a heat spreader showing intergrowth between larger diamond crystals;

FIG. 6 is a cross-sectional profile view of another embodiment of a heat spreader showing intergrowth between diamond crystals;

FIG. 7 is a cross-sectional profile view of an embodiment of a heat spreader also functioning as a heat sink;

FIG. 8 is a cross-sectional profile view of one embodiment of a heat spreader having protruding diamond monocrystals to interface with a heat sink;

FIG. 9 is a cross-sectional profile view of one embodiment of a heat spreader having protruding diamond monocrystals interfacing with a heat sink and a heat source;

FIG. 10 is a cross-sectional profile view of one embodiment of a heat spreader having a bonding material between the support material and the heat source;

FIG. 11 is a cross-sectional profile view of one embodiment of a heat spreader bonded to a heat source along the edges;

FIG. 12 shows one embodiment of a heat spreader assembly using a biasing member to keep the components firmly pressed together;

FIG. 13 is a cross-sectional profile view of one embodiment of a heat spreader containing diamond monocrystals aligned with vias of an integrated circuit;

FIG. 14 is a perspective view showing one method of creating a heat spreader using a cylindrical volume produced in a high-pressure, high-temperature press;

FIG. 15 is a perspective view showing another method of creating a heat spreader using a cylindrical volume produced in a high-pressure, high-temperature press; and

FIG. 16 shows one embodiment of a heat spreader made up of several sections.

### DETAILED DESCRIPTION OF THE INVENTION

It will be readily understood that the components of the present invention, as generally described and illustrated in the Figures herein, could be arranged and designed in a wide variety of different configurations. Thus, the following more detailed description of the embodiments of apparatus and methods in accordance with the present invention, as represented in the Figures, is not intended to limit the scope of the invention, as claimed, but is merely representative of certain examples of presently contemplated embodiments in accordance with the invention. The presently described embodiments will be best understood by reference to the drawings, wherein like parts are designated by like numerals throughout.

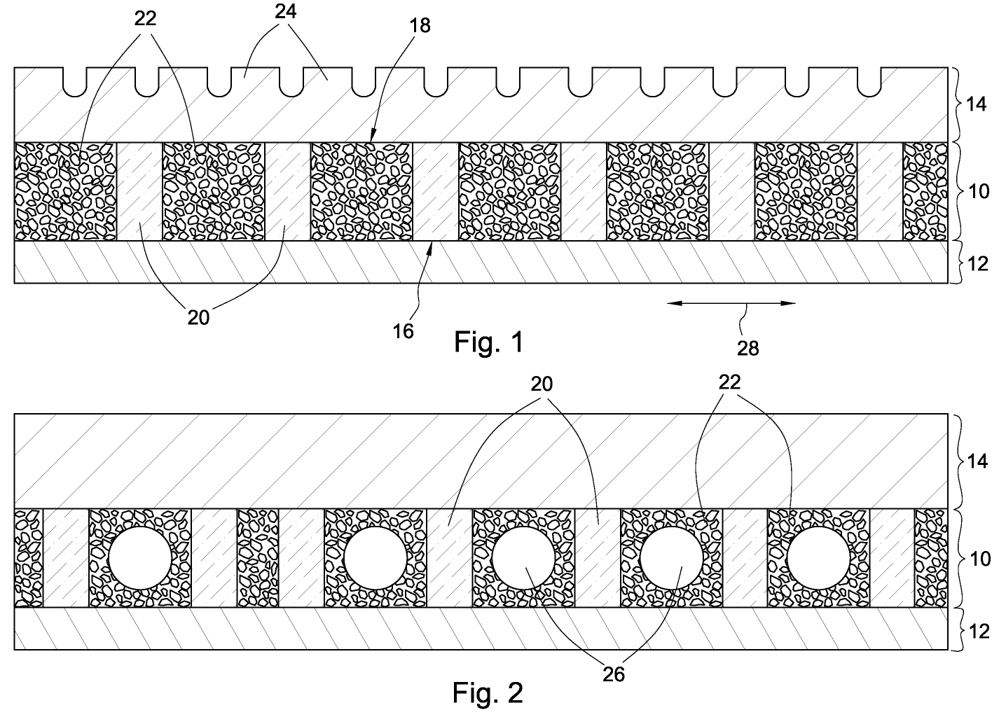

Referring to FIG. 1, in one embodiment, a heat spreader 10 in accordance with the invention may be positioned between and be in thermal contact with a heat source 12 and a heat sink 14. A heat source 12 may include, for example, an integrated circuit such as a microprocessor, a digital signal processor (DSP), or other semiconductor device. In certain, embodiments, a thermal interface material, such as thermally conductive grease, may be applied between the heat spreader 10 and the heat source 12, the heat spreader 10 and the heat sink 14, or both, to improve the thermal contact therebetween. A heat sink 14 may be fabricated of a good thermal conductor, such as a copper or aluminum alloy, to store and dissipate heat absorbed from the heat spreader 10 into the air, a liquid, a gas, or a cryogenic fluid. As illustrated, a heat sink 14 may incorporate fins 24 or other protrusions 24 to provide increased surface area to aid in dissipating heat.

A heat spreader 10 in accordance with the invention may be used to dissipate or disperse concentrations of heat from the heat source 12 prior to conducting it to the heat sink 14. That is, a heat spreader 10 may disperse heat energy from “hot spots” through its volume to efficiently and more evenly transfer heat to the heat sink 14. To achieve this, the heat spreader 10 may include in input interface 16 to conduct heat from the heat source 12, and an output interface 18 to conduct heat to a heat sink 14.

A heat spreader 10 in accordance with the invention may include one or more diamond monocrystals 20 embedded in a support material 22 to effectively dissipate heat generated by the heat source 12. The diamond monocrystals 20 may extend from the input interface 16 to the output interface 18 and have a surface contiguous with each interface 16, 18. These diamond monocrystals 20 provide uninterrupted thermal paths through the heat spreader 10. As will be explained in more detail hereafter, h certain embodiments, the diamond monocrystals 20 may be strategically placed within the support material 22 to conduct heat away from “hot spots” of the heat source 12.

The diamond monocrystals 20 may be either natural or synthetic, and be of various types, including type IA, IB, IIA, or IIB, although the thermal conductivity may vary considerably (e.g., 600-3000 W/m/K) based on the diamond type. Type IIA diamonds may be preferred due to their high thermal conductivity, but less preferred due to their high cost. Similarly, diamonds having occlusions, undesirable colors, impurities, or other defects may be less expensive, but may also have reduced thermal conductivity. Ideally, these tradeoffs may be adjusted to maximize thermal conductivity while minimizing cost. In certain embodiments, an HPHT press may be used to actually improve the thermal conductivity of some diamonds by improving or removing defects in a diamond's lattice structure, dispersing aggregates of nitrogen, or the like. Thus, an HPHT press may be used to improve the thermal conductivity of less expensive and less thermally conductive diamond monocrystals 20 for use with the heat spreader 10.

In certain embodiments, the support material 22 is constructed of a material of high thermal conductivity, but lower than that of the diamond monocrystals 20. For example, in one embodiment, the support material 22 may be constructed of polycrystalline diamond (PCD), the thermal conductivity of which may exceed 700 W/m/K. Such a heat spreader 10 may be produced by placing one or more diamond monocrystals in the PCD diamond particles prior to sintering the diamond particles together using high-pressure, high-temperature (HPHT) technology. If necessary, the input and output interfaces 16, 18, including the diamond monocrystals 20, may then be ground and polished to form a smooth surface.

In other embodiments, the support material 22 may be constructed of materials such as silicon, metals (e.g., copper, aluminum, etc.), cubic boron nitride, ceramics, carbides, polycrystalline silicon, or the like. Ideally, the support material 22, like the diamond monocrystals 20, is selected to have a high thermal conductivity, although it will have a lower thermal conductivity than the monocrystals 20.

One advantage of embedding diamond monocrystals 20 in a support material 22 is the ability to create intimate contact between the monocrystals 20 and the support material 22. This is achieved despite the inert nature of diamond which makes it difficult to bond it to other materials. Because the support material 22 surrounds the diamond monocrystals 20, it effectively “traps” the monocrystals 20 to create intimate contact therewith. This intimate contact improves the thermal contact between the monocrystals 20 and the support material 22, improving the spreader's ability to conduct heat laterally 28 through the spreader 10.

Referring to FIG. 2, in certain embodiments, a heat spreader 10 in accordance with the invention may incorporate one or more channels 26 in the support material 22 to dissipate heat to a fluid, such as air or a liquid. The fluid may flow through the channels 26 at a rate selected to provide the desired cooling. In certain embodiments, the spreader 10 may also be in thermal contact with a heat sink 14 to provide additional heat dissipation. The channels 26 may be formed in the support material 22 by drilling or other cutting techniques such as using an electrical discharge machine (EDM). An electrical discharge machine may be effective, for example, to form channels 26 in a support material 22 of polycrystalline diamond.

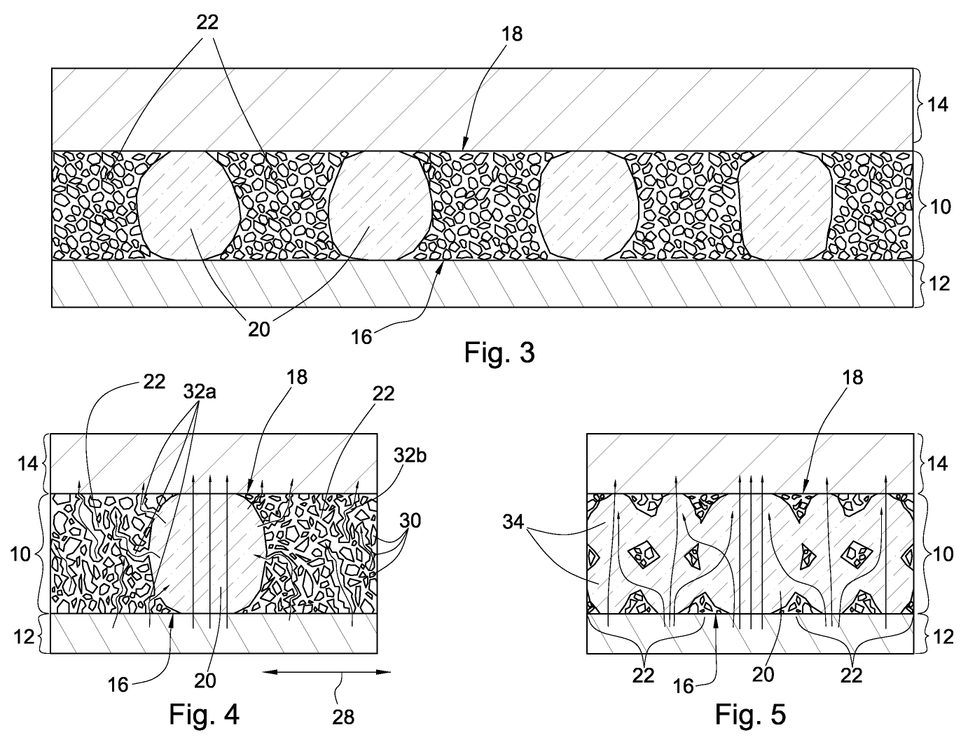

Referring to FIG. 3, in certain embodiments, the heat spreader 10 may include rough (i.e., uncut) diamond monocrystals 20 embedded in the support material 22. Like the cut diamonds 20 illustrated in FIGS. 1 and 2, the rough diamonds 20 may create an interrupted thermal path between the input interface 16 and the output interface 18 by extending between the interfaces 16, 18. To achieve this, the input interfaces 16, 18, including surfaces of the rough diamonds 20, may be ground and/or polished to form smooth interface surfaces 16, 18.

In certain cases, rough diamonds 20 may be significantly less expensive than cut diamonds. Furthermore, rough diamonds 20 may generally be larger than cut diamonds 20 by preserving weight that would otherwise be removed in the cutting process. Consequently, these larger diamonds 20 may also conduct more heat due to the additional material. Another advantage of using rough diamonds 20 may also include improved contact between the support material 22 and the diamonds 20. That is, the rough or irregular outer surface of rough diamonds 20 may provide a better grip to the support material 22.

Referring to FIG. 4, in certain embodiments, where the support material 22 is made of polycrystalline diamond, diamond particles 30 of the support material 22 may be intergrown with each other and with the diamond monocrystal 20 to improve the thermal conductivity of the support material 22 and the heat spreader 10 more generally. For example, upon sintering the support material 22 and the diamond monocrystal 20 in an HPHT press, the diamond particles 30 may intergrow to generate thermal pathways through the support material 22, thereby improving the thermal conductivity of the support material 22. These thermal pathways may, in certain cases, intergrow with the diamond monocrystal 20 during the HPHT process. This may create a network of thermal pathways through the heat spreader 10.

For example, in addition to conducting heat directly through the monocrystal 20, certain thermal pathways 32a may merge with or branch off from a monocrystal 20, creating additional paths for conducting heat. Some of these branches 32a may extend to the input and output interfaces 16, 18. Other isolated pathways 32b, independent from the monocrystals 20, may be created within the support material 22, improving the thermal conductivity of the support material 22. These additional thermal pathways 32a, 32b, in addition to providing improved conductivity between the input interface 16 and the output interface 18, may also imp rove thermal conductivity laterally 28 through the heat spreader 10.

Referring to FIG. 5, in other embodiments, the support material 22 may contain larger diamond particles 34, although these crystals particles will typically be smaller than the monocrystal 20. For example, a pair (or a larger number) of diamond particles 34 together could extend from the input interface 16 to the output interface 18. Like the previous example, these larger particles 34 may be intergrown using HPHT technology to create a continuous thermal pathway between the interfaces 16, 18. Similarly, these diamond particles 34 may also be intergrown with a monocrystal 20 using the same technique. One advantage of using the larger particles 34 is that they may be significantly less expensive than a monocrystal 20 while providing a similar result. Larger particles 34 may also provide improved thermal conductivity compared to smaller particles by reducing the number of thermal barriers in the support material 22.

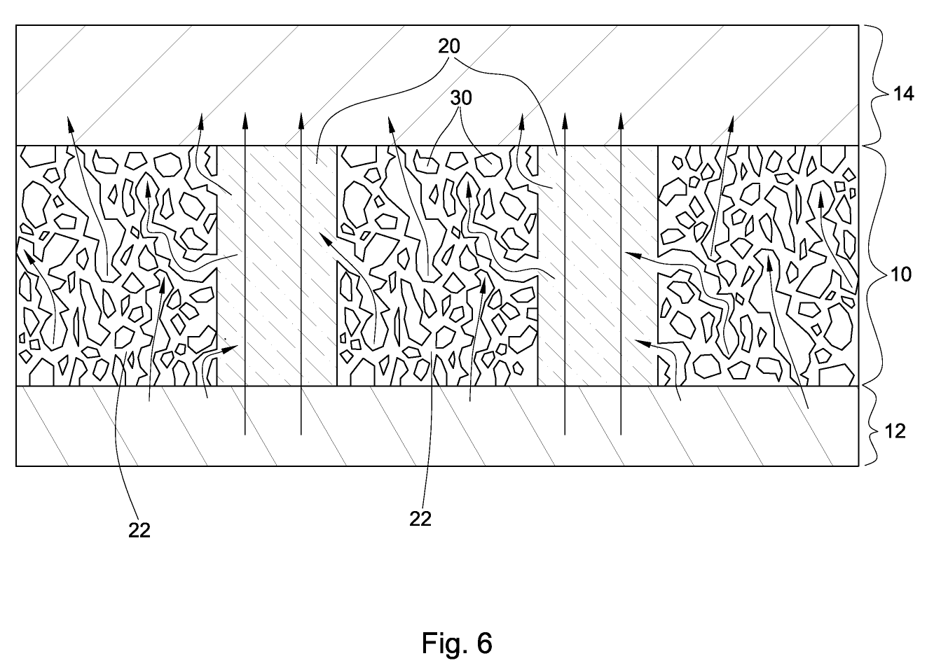

Referring to FIG. 6, in other embodiments, a heat spreader 10 may include cut diamond monocrystals 20 intergrown with diamond particles 30 of the support material 22. Like the previous example, this intergrowth may be used to provide a network of thermal pathways through the heat spreader 10.

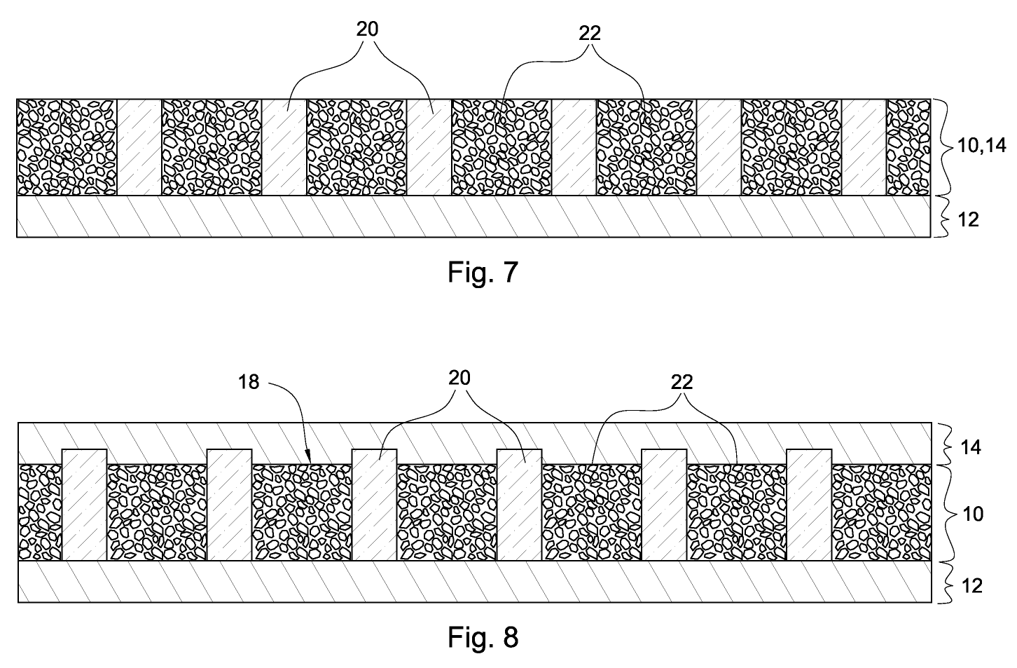

Referring to FIG. 7, in certain embodiments, a heat spreader 10 may also function as a heat sink 14. For example, although the diamond monocrystals 20 typically have a very low thermal capacity, the support material 22 may be chosen to have a higher desired thermal capacity, such as by including metals or other materials of higher thermal capacity in the support material 22. In this embodiment, the diamond monocrystals 20 may be used to conduct heat from “hot spots” or other heat concentrations in the heat source 12 into the support material 22. In certain embodiments, the support material 22 may be provided with fins, channels, protrusions, or the like, to dissipate heat stored therein to a fluid, such as air, liquid, gas, or a cryogenic fluid.

Referring to FIG. 8, in certain contemplated embodiments, the heat spreader 10 may be shaped such that the diamond monocrystals 20 protrude from the output interface 18. A heat sink 14 may include corresponding notches or indentations to receive and make contact with the monocrystals 20. This design may aid in attaching the heat sink 14 to the heat spreader 10 and provide more intimate contact between the diamond monocrystals 20 and the heat sink 14. Furthermore, the contact surface area between the diamond monocrystals 20 and the heat sink 14 is increased significantly using this configuration, which may provide improved heat transfer.

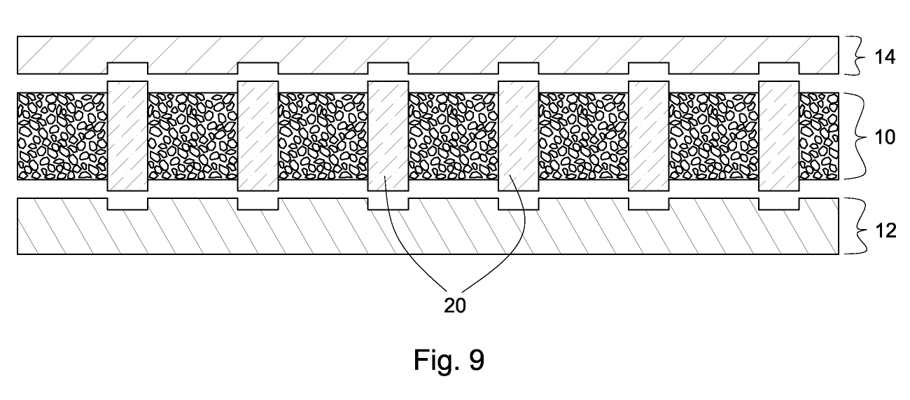

Referring to FIG. 9, in a similar manner, a heat source 12 may also include notches or indentations b interface with protruding diamond monocrystals 20. Like the previous example, this may aid in attaching the spreader 10 to the heat source 12, provide intimate contact between the diamond crystals 20 and the heat source 12, and increase the contact surface area between the two.

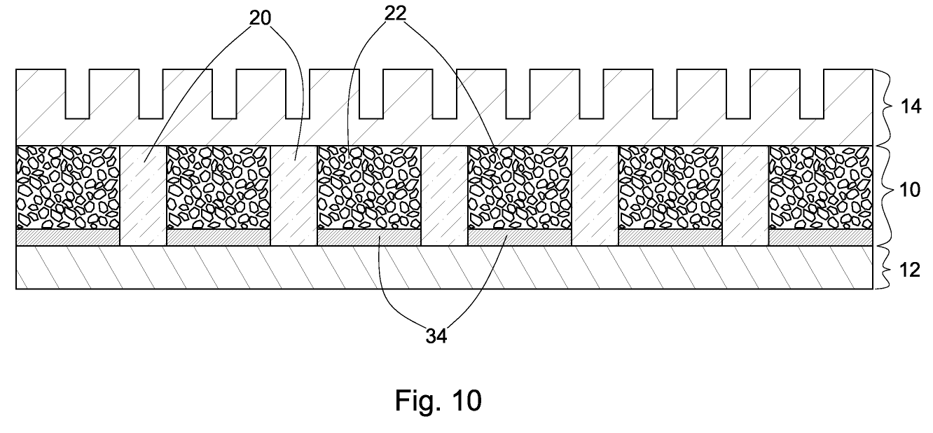

Referring to FIG. 10, in certain embodiments, a heat spreader 10 may be bonded directly to a heat source 12. In selected embodiments, because of the inert nature of diamond monocrystals 20 making it very difficult to adhere diamond to another material, the support material 22 may be bonded directly to a heat source 12 with a braze 34 or other thermally conductive material 34. Accordingly, the support material 22 may be selected to provide a surface more suitable for bonding to the heat source 12. In certain embodiments, the braze 34 may contain conductive grains, such as diamond particles, to aid in conducting heat between the heat source 12 and the heat spreader 10. The braze 34 may also keep the diamond monocrystals 20 in firm contact with the heat source 12, providing better thermal contact between the two.

In certain embodiments, materials for the heat spreader 10 and heat source 12 may be selected to ensure that the heat spreader 10 does not delaminate from the heat source 12 upon heating or cooling as a result of differences in coefficients of thermal expansion. For example, a heat spreader 10 primarily made up of diamond and polycrystalline diamond and an integrated circuit 12 primarily made of silicon have sufficiently low coefficients of thermal expansion that they can be bonded together without a high risk of delamination.

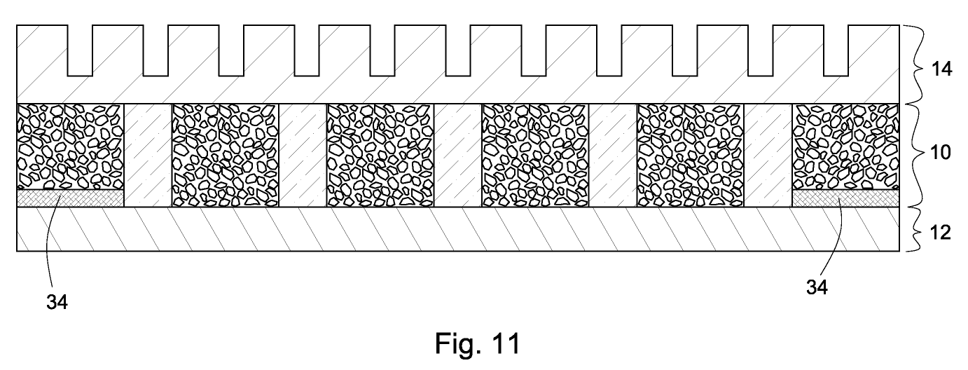

Referring to FIG. 11, in other embodiments, a braze 34 may be provided along only the edges of the heat spreader 10 or heat source 12 to bond the two together. In addition to being easier to implement, this embodiment may also be less prone to delaminate.

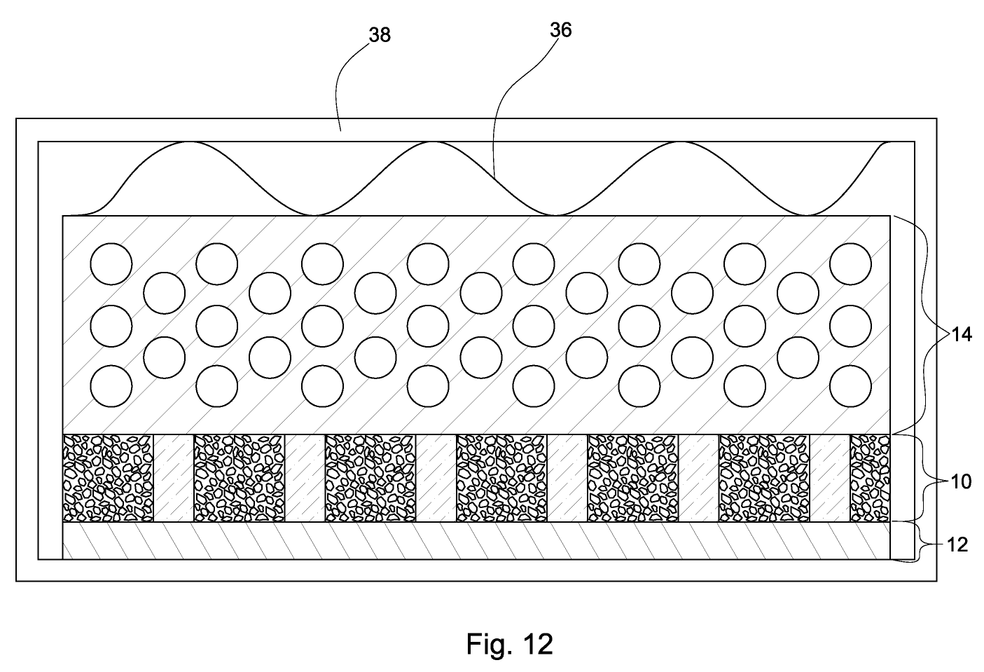

Referring to FIG. 12, in other embodiments, a heat spreader 10, heat source 12, and heat sink 14 may be held firmly together by a biasing member 36, such as a spring 36. For example, in one embodiment, the heat spreader 10, heat source 12, and heat sink 14 may include a structure 38. A spring 36 may exert force against the structure 38 on one side and the heat sink 14 on the other. The structure 38 may retain the heat source 12 on the other side to keep the components 10, 12, 14 firmly pressed together.

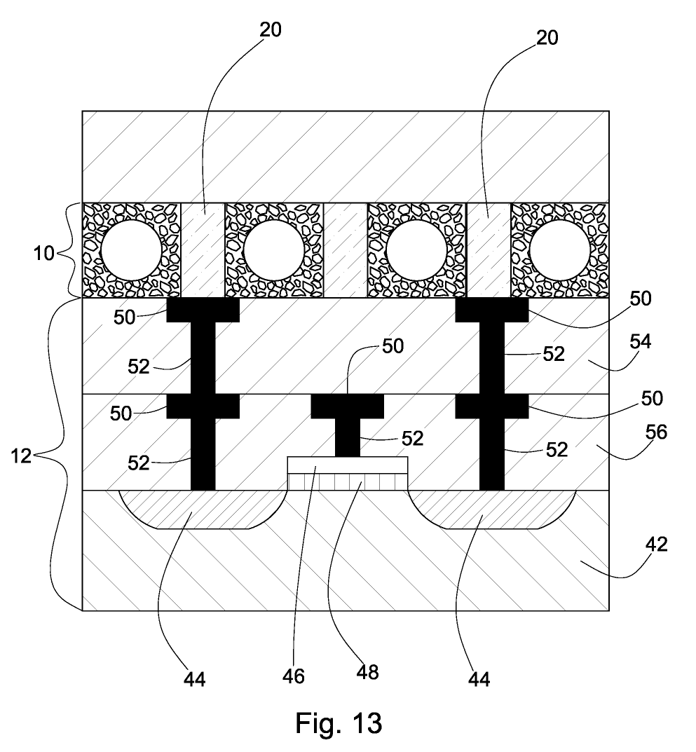

Referring to FIG. 13, a typical integrated circuit 12 may be fabricated on a substrate 42 and include terminals 44, 46. For example, an integrated circuit 12 may include doped well terminals 44 and a transistor gate structure terminal 46. A dielectric material 48 may separate the transistor gate structure 46 from the substrate 42. While only several terminals 44, 46 are depicted for the sake of clarity, it should be understood that an integrated circuit 12 may include hundreds, thousands, or millions of terminals 44, 46. These terminals 44, 46 may be interconnected to perform predetermined logical functions through an interconnected network of electrical conductors 50 and vias 52.

The electrical conductors 50 may be arranged on electrically isolated layers 54, 56 which may be referred to as metal layers. The electrically isolated layers 54, 56 may be constructed of a dielectric material to insulate the electrical conductors 50 from each other. Electrically conductive vias 52 may transverse the electrically isolated layers 54, 56 to connect the terminals 44, 46 and electrical conductors 50 to create a desired circuit.

As previously mentioned, significant temperature variations, or “hot spots,” may occur in an integrated circuit's metal layers, which may include both the electrical conductors 50 and the vias 52. Diamond monocrystals 20 of a heat spreader 10 may be aligned with the conductors 50 or vias 52 of the integrated circuit 12, as illustrated in FIG. 13. These monocrystals 20 may be used to diffuse and draw heat away from these areas.

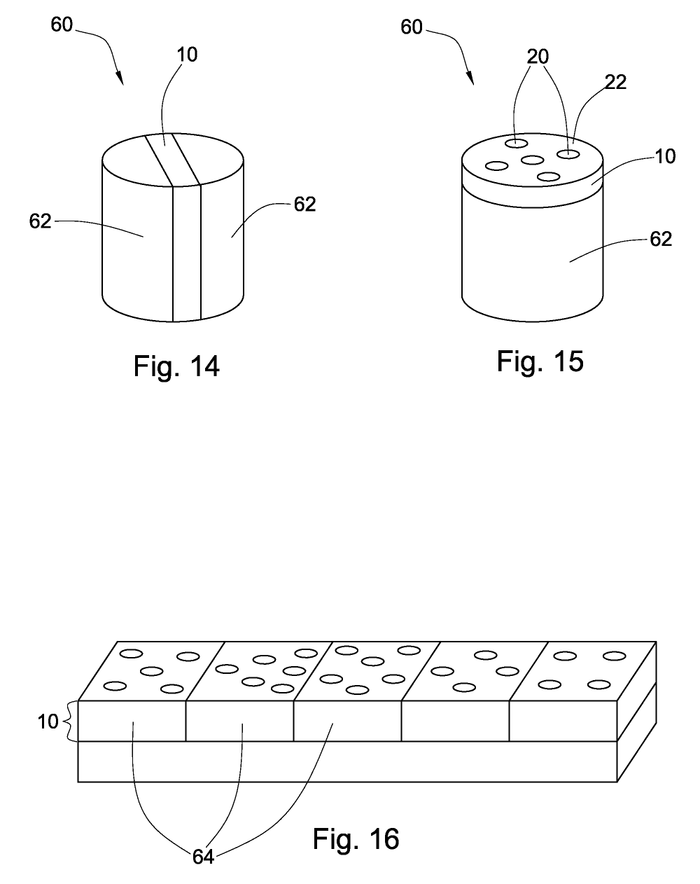

Referring to FIGS. 14 and 15, to produce a heat spreader 10 in accordance with the invention, a heat spreader 10 containing diamond monocrystals 20 embedded within a polycrystalline diamond support material 22 may, in certain embodiments, be formed within a cylindrical volume 60 produced in an HPHT press. For example, high-pressure polycrystalline diamond may be produced from mixtures of diamond powder. These powders may be mixed to provide optimal packing and placed adjacent to a tungsten carbide substrate 62, which may also contain a cobalt binder.

As the volume 60 is subjected to the high temperatures and pressures of an HPHT press, cobalt, which is a diamond synthesis catalyst, flows out of the tungsten carbide substrate 62 and wets the diamond powders of the heat spreader 10. Sintering of the heat spreader 10 is achieved by catalytic dissolution and re-growth of diamond and plastic deformation of the diamond crystals at high temperature due to high inter-crystalline contact pressures. This process results in a solid volume 60. If desired, the carbide substrate 62 and most of the included catalyst may be removed through grinding and acid leaching. In other embodiments, part of the substrate 62 may be left attached to the spreader 10. It is contemplated that the remaining substrate 62 could be used as a heat sink 14 or to provide a metalized surface to more easily bond the heat spreader 10 to the heat source 12 or the heat sink 14.

FIG. 14 shows one embodiment of a spreader 10 positioned vertically along an axial direction of a cylinder 60. This technique may be used to create a generally rectangular spreader 10 and prevent waste of materials, and may be applied to a rectangular heat source 12 such as an integrated circuit 12. FIG. 15 shows a spreader 10 formed in a circular shape around the circumference of the volume 60. As is visible in this embodiment, the spreader 10 includes support material 22 and diamond monocrystals 20. Such a spreader 10 maybe applied to a heat source 12 in its circular form, or alternatively, the edges of the spreader 10 may be cut or ground down to form a rectangular or other shape for application to a heat source 12.

Referring to FIG. 16, because the dimensions of a heat spreader 10 may be limited by the capabilities of current HPHT presses or other technology, in certain embodiments, a heat spreader 10 may be assembled from several sections 64. Each of these sections 64 may be produced, for example, using the techniques or processes described in association with FIGS. 14 and 15. In certain embodiments, the sections 64 may be brazed or otherwise attached together, or a conductive material, such as thermally conductive grease, may be used between the interfaces. This will improve the spreader's ability to dissipate heat laterally through the spreader 10 from one section 64 to another 64.

The present invention may be embodied in other specific forms without departing from its essence or essential characteristics. The described embodiments are to be considered in all respects only as illustrative, and not restrictive. The scope of the invention is, therefore, indicated by the appended claims, rather than by the foregoing description. All changes within the meaning and range of equivalency of the claims are to be embraced within their scope.

We claim:

1. A composite heat spreader comprising:
an input interface to conduct heat from a heat source:
an output interface to transfer heat to a heat sink;
a support material comprising a first thickness between the input interface and the output interface; and
a diamond monocrystal embedded in the support material, the diamond monocrystal comprising a second thickness which is at least 20% the first thickness.

2. The composite heat spreader of claim 1, wherein the diamond monocrystal extends from the input interface to the output interface.

2. The composite heat spreader of claim 1, wherein the diamond monocrystal is positioned within the support material to align with at least one of a hot spot, a via, and a conductor of the heat source.

3. The composite heat spreader of claim 1, wherein the support material comprises diamond grains.

4. The composite heat spreader of claim 3, wherein the diamond grains are compacted and sintered together to form polycrystalline compact diamond.

5. The composite heat spreader of claim 4, wherein at least a portion of the diamond grains are intergrown with each other and with the diamond monocrystal.

6. The composite heat spreader of claim 1, wherein the support material comprises a material selected from the group consisting of silicon, a metal, cubic boron nitride, a ceramic, a carbide, polycrystalline silicon, and combinations thereof.

7. The composite heat spreader of claim 1, wherein at least one of the input interface and the output interface are polished.

8. The composite heat spreader of claim 1, wherein the diamond monocrystal is one of a rough and finished diamond.

9. The composite heat spreader of claim 1, wherein at least a portion of the support material is metalized.

10. The composite heat spreader of claim 1, wherein the heat source is an integrated circuit.

11. The composite heat spreader of claim 1, wherein the second thickness is at least 25%, 35%, 50% or 70% the first thickness.

12. A method for spreading heat generated by a heat source, the method comprising:
conducting, at an input interface, heat from a heat source:
transferring, at an output interface, heat to a heat sink;
providing a support material comprising a first thickness between the input interface to the output interface; and
embedding a diamond monocrystal in the support material, the diamond monocrystal comprising a second thickness which is at least 20% of the first thickness.
The method of claim 1, wherein the diamond monocrystal extends from the input interface to the output interface.

13. The method of claim 12, further comprising positioning the diamond monocrystal within the support material to align with at least one of a hot spot, a via, and a conductor of the heat source.

14. The method of claim 12, wherein providing a support material comprises embedding diamond grains in the support material.

15. The method of claim 14, further comprising compacting and sintering the diamond grains to form polycrystalline compact diamond.

16. The method of claim 15, further comprising intergrowing at least a portion of the diamond grains with each other and with the diamond monocrystat

17. The method of claim 12, wherein providing a support material comprises providing a material selected from the group consisting of silicon, a metal, cubic boron nitride, a ceramic, a carbide, polycrystalline silicon, and combinations thereof.

18. The method of claim 12, further comprising polishing at least one of the input interface and the output interface.

19. The method of claim 12, wherein the diamond monocrystal is one of a rough and finished diamond.

20. The method of claim 12, further comprising metalizing at least a portion of the support material.

21. A heat spreading assembly comprising:
an integrated circuit;
a heat sink;
a composite heat spreader inserted between the integrated circuit and the heat sink, the composite heat spreader comprising:
an input interface to conduct heat from the integrated circuit:
an output interface to transfer heat to the heat sink;
a support material comprising a first thickness between the input interface and the output interface; and
a diamond monocrystal embedded in the support material, the diamond monocrystal comprising a second thickness which is at least 20% of the first thickness.
